(19) United States
(12) Patent Application Publication
(10) Pub. No.: US 2002/0033694 A1
(43) Pub. Date: Mar. 21, 2002

(54) METHOD TO DETERMINE FUNDAMENTAL AND HARMONIC OSCILLATIONS OF A MEASURED ELECTRICAL QUANTITY

(76) Inventors: TEVFIK SEZI, RALEIGH, NC (US); THOMAS RECK, BERLIN (DE)

Correspondence Address: KENYON & KENYON, ONE BROADWAY, NEW YORK, NY, 10004, US

(21) Appl. No.: 09/254,463

(22) PCT Filed: Sep. 4, 1997
(86) PCT No.: PCT/DE97/01971

(30) Foreign Application Priority Data
Sep. 5, 1996 (DE) 196 37 676.9

(51) Int. Cl. G01R 19/00

(52) U.S. Cl. 324/76.11

(57) ABSTRACT

A method of determining the fundamental component and the harmonics (I′(ω)) of a measured electric quantity (M) is described, where the measured quantity (M) is processed by an analog signal processing circuit (15), the processed measured quantity is sampled and subject to an analog-digital conversion with a subsequent discrete Fourier transform (DFT).

To be able to determine very accurately the fundamental component and the harmonics (I′(ω)) of the measured electric quantity (M) despite the use of a relatively low quality signal processing circuit (15), a correction factor (k(ω)) characterizing the absolute value and phase of the frequency response characteristic of the signal processing circuit (15) is obtained from a memory (18). The measured values (I(ω)) of the absolute value and phase of the fundamental component and the harmonics after the Fourier transform are corrected with the correction factor (k(ω)).

With a known arrangement for determining the fundamental component and the harmonics of a measured electric quantity (Klaus Weighardt, “Im Blickpunkt: Digitale Signalverarbeitung, 1. Teil: Datenerfassung/digitale Filter” [Focal Point: Digital Signal Processing, Part 1: Data Acquisition, Digital Filters], Elektronik, vol. 2 (Jan. 23, 1987), pages 89 through 96, page 93 in particular), before a measured electric quantity is sampled, it is processed by a signal processing circuit which limits the frequency band of the measured quantity. This prevents anti-aliasing errors in the subsequent sampling. High technological demands are made of this signal processing circuit to prevent corruption of the signal and thus measurement errors due to the signal processing circuit.

The object of the present invention is to provide a method of accurately determining the fundamental component and the harmonics of a measured electric quantity of a polyphase electric power transmission line with which the fundamental component and the harmonics of the measured electric quantity can be determined with a high accuracy despite the use of a relatively low quality signal processing circuit.

This object is achieved according to the present invention with a an arrangement with a signal processing circuit connected to one phase of the power transmission line and having at the input end at least one current or voltage transformer connected to that phase and a low-pass filter downstream from the current or voltage transformer, with a series circuit downstream from the signal processing circuit, with a sampling device, a downstream analog-digital converter and a device for the discrete Fourier transform (DFT), a memory for storing a frequency-dependent correction factor obtained by previous one-time calibration measurements of the signal processing circuit, and a correction arrangement which is connected on the one hand to the memory and on the other hand to the device for the discrete Fourier transform and delivers at one output the fundamental component and the harmonics of the measured electric quantity.

An important advantage of this arrangement is that even electric components having high tolerances can be used to manufacture the signal processing circuit because the measurement errors caused by the signal processing circuit are corrected by the frequency-dependent correction factor. Measurement errors of less than 1% can be achieved easily.

To be able to characterize several phases as well as the neutral conductor of the power transmission line with the arrangement according to the present invention, it is regarded as advantageous if the arrangement has additional current transformers or additional voltage transformers, each with an additional downstream low-pass filter, and a multiplexer, which is connected to the one low-pass filter and the additional low-pass filters on the one hand and to the series circuit on the other hand.

To illustrate the present invention,

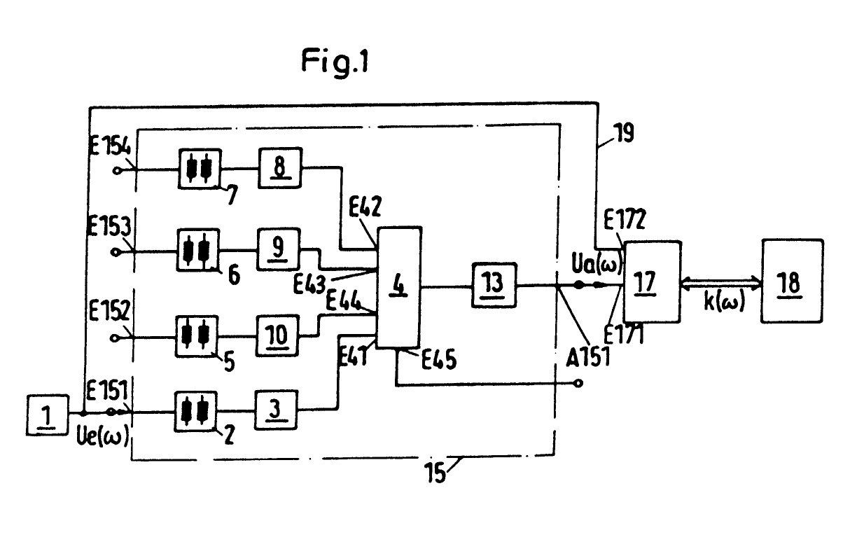

FIG. 1 shows a measurement circuit for determining a frequency-dependent correction factor which characterizes the absolute value and phase of the frequency response characteristic of a signal processing circuit, and

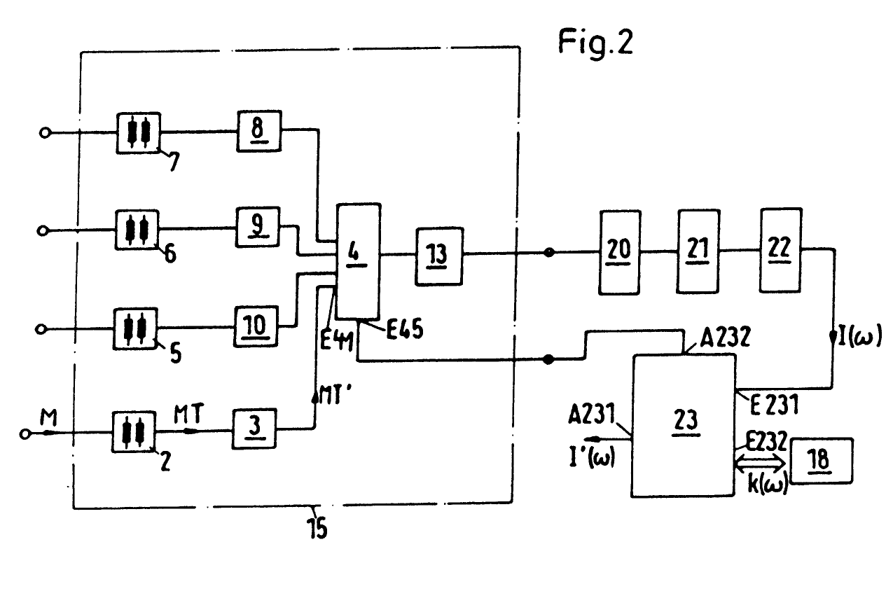

FIG. 2 shows an embodiment of an arrangement according to the present invention for determining the fundamental component and the harmonics of a measured electric quantity.

A current transformer 2 with a downstream low-pass filter 3 at its output is connected to a function generator 1 shown in FIG. 1. The output of low-pass filter 3 is connected to an input E41 of a multiplexer 4. Another low-pass filter 8, 9 and 10 is connected to each of additional current transformers 5, 6 and 7. Additional low-pass filters 8, 9 and 10 are connected at the output to additional inputs E42, E43 and E44 of multiplexer 4. Downstream from multiplexer 4 is an amplifier 13. One current transformer 2, additional current transformers 5, 6 and 7, one low-pass filter 3, additional low-pass filters 8, 9 and 10, multiplexer 4 and amplifier 13 form an analog signal processing circuit 15 with one output A151 and inputs E151, E152, E153 and E154. Function generator 1 is thus connected to one current . . . the frequency response of analog signal processing circuit 15 is determined as part of the production of an arrangement according to the present invention. To do so, with the help of function generator 1, a sinusoidal input variable Ue(ω) of a predetermined circuit frequency ω and a predetermined amplitude Ae(ω) are supplied to current transformer 1, for example, or to analog signal processing circuit 15 at input E151. Using precision measuring instrument 17, amplitude Aa(ω) of output variable Ua(ω) subsequently available at output A151 of signal processing circuit 15 and its phase angle Φa(ω) relative to input variable Ue(ω) are measured. A quotient Ae(ω)/Aa(ω) is determined from amplitude Ae(ω) of input variable Ue(ω) and amplitude Aa(ω) of output variable Ua(ω). A complex correction factor k(ω) is formed with the quotient Ae(ω)/Aa(ω) and with the phase angle φa(ω):

$$k ( ω ) = \frac{Ae ( ω )}{Aa ( ω )} \cdot exp [ - j \cdot ϕ a ( ω ) ]$$

Correction factor k(ω) is determined in this way for the fundamental component and for the harmonics to be determined, e.g., for the first, second, fourth, sixth, eighth, tenth and twelfth harmonics.

Frequency-dependent correction factor k(ω) determined in this way is transmitted to memory 18 and stored there. Storage of complex correction factor k(ω) can be accomplished by storing quotient Ae(ω))/Aa(ω) and phase angle φa(ω), for example.

Likewise, additional correction factors are also determined by using current transformers 5, 6 and 7 for subsequent correction of the measured electric quantities measured by way of these current transformers; for this purpose, the respective input variable to be measured must be switched through with multiplexer 4 to output A151 of signal processing circuit 15.

FIG. 2 shows an arrangement for carrying out the method according to the present invention, where the elements already explained in conjunction with FIG. 1 have the same reference numbers as in FIG. 1.

As explained in conjunction with FIG. 1, signal processing circuit 15 has current transformers 2, 5, 6 and 7, low-pass filters 3, 8, 9 and 10, multiplexer 4 and amplifier 13. Downstream from amplifier 13 and signal processing circuit 15 is a sampling device 20, which is connected at the output to an analog-digital converter 21. The output of analog-digital converter 21 is connected to a device 22 for discrete Fourier transform (DFT) which is itself connected to a correction arrangement 23 by an input E231. Another input E232 of correction arrangement 23 is connected to memory 18. An output A231 of correction arrangement 23 forms the output of the arrangement according to the present invention. Another output A232 of correction arrangement 23 is connected to an additional input E45 of multiplexer 4.

In the following description of the method according to the present invention it is assumed that current transformer 2 measures a phase current, which is converted by a series transformer (not shown) connected to the input side of current transformer 2, in one phase of a polyphase power transmission line (also not shown).

A measured electric quantity M is converted to a measured current quantity MT in current transformer 2. Measured current quantity MT is transmitted from current transformer 2 to low-pass filter 3. In low-pass filter 3, the frequency spectrum of measured current quantity MT is limited in low-pass filter 3, forming a band-limited measured current quantity MT′ to prevent anti-aliasing errors in sampling in sampling device 20. Band-limited measured current quantity MT′ goes to one input E41 of multiplexer 4, where it is switched through to amplifier 13. From there, the band-limited and amplified measured current quantity is transmitted to sampling device 20, where it is sampled. The samples go to analog-digital converter 21 and then to device 22 for discrete Fourier transform (DFT), where a discrete Fourier transform is performed, forming an intermediate measured quantity I(ω). Intermediate measured quantity I(ω) corresponds to the band-limited, amplified measured current quantity in the frequency range. This intermediate measured quantity I(ω) is sent to correction arrangement 23. Frequency-dependent correction factor k(ω) is read out of memory 18 and transmitted to correction arrangement 23. Then complex multiplication of intermediate measured quantity I(ω) by frequency-dependent correction factor k(ω) is performed. Both the absolute value and the phase of intermediate measured quantity I(ω) are corrected by this complex multiplication, so that the absolute value and the phase of the fundamental component and the harmonics I′(ω) of measured electric quantity M can be described by the following equations:

$$\begin{matrix}{I}^{′} ( ω ) = I ( ω ) \cdot k ( ω ) ⇒ \vert {I}^{′} ( ω ) \vert = \vert I ( ω ) \vert \cdot \frac{Ae ( ω )}{Aa ( ω )} \\ ⇒ ϕ ( {I}^{′} ( ω ) ) = ϕ ( I ( ω ) ) = ϕ a ( ω )\end{matrix}$$

The complex multiplication can be implemented technically by a multiplication and addition unit.

The fundamental component and the harmonics I′(ω) are supplied at one output A231 of correction arrangement 23. Thus, the measurement errors caused by the frequency response of analog signal processing circuit 15 for the fundamental component and the harmonics to be measured are corrected in correction arrangement 23, so that error-free measured values for the amplitude and phase angle are supplied at one output A231 of correction arrangement 23.

In this way, the absolute value and phase angle of the fundamental component and, for example, the first, second, fourth, sixth, eighth, tenth and twelfth harmonics can be corrected in correction arrangement 23.

Multiplexer 4 can be controlled via additional output A232 of correction arrangement 23, so that secondary quantities of additional current transformers 5, 6 and 7 can also be detected. If additional current transformers 5, 6 and 7 as well as current transformer 2 are connected to the power transmission line via series transformers, three phases of the power transmission line and the neutral conductor can be detected with the measurement technology. Instead of the current transformers, voltage transformers may also be used if voltage values are to be determined by the method according to the present invention. This requires that correction values have previously been picked up with voltage transformers in the signal processing circuit.

In conclusion, it should be pointed out that the method according to the present invention is carried out in practice with an electronic data processing system.

1. Arrangement for determining the fundamental component and the harmonics (I′(ω)) of a measured electric quantity (M) of a polyphase electric power transmission line, with
a signal processing circuit (15) connected to one phase of a power transmission line and having at the input end at least one current transformer (2) connected to that phase or a voltage transformer and having a low-pass filter (3) downstream from the current transformer (2) or voltage transformer,
a series circuit downstream from the signal processing circuit (15) with a sampling device (20), a downstream analog-digital converter (21) and a device (22) for discrete Fourier transform (DFT),
a memory (18) for storing a frequency-dependent correction factor (k(ω)) which has been determined by previous one-time calibration measurements of the signal processing circuit (15), and
a correction arrangement (23) which
is connected on the one hand to the memory (18) and on the other hand to the device (22) for the discrete Fourier transform (DFT), and
delivers the fundamental component and the harmonics (I′(ω) of the measured electric quantity (M) at one output (A231).

2. Arrangement according to claim 1, characterized in that the arrangement for detecting additional phases of the power transmission line has
additional current transformers (5, 6, 7) or additional voltage transformers, each of which has an additional downstream low-pass filter (8, 9, 10), and
a multiplexer (4) which is connected to the one low-pass filter (3) and the additional low-pass filters (8, 9, 10) and is also connected to the series circuit.
